(19) United States
(12) Patent Application Publication
(10) Pub. No.: US 2001/0006357 A1
(43) Pub. Date: Jul. 5, 2001

(54) Oscillation/amplification circuit which is unsusceptible to noise and capable of supplying a stable clock

(76) Inventor: Hiroaki Yamamoto, Kawasaki-shi (JP)

Correspondence Address: Oblon, Spivak, McClelland, Mailer & Neustadt, P.C., Fourth Floor, 1755 Jefferson Davis Highway, Arlington, VA, 22202, US

(21) Appl. No.: 09/745,470

(22) Filed: Dec. 26, 2000

(30) Foreign Application Priority Data
Dec. 27, 1999 (JP) PATENT 11-370872

(51) Int. Cl. H03B 5/36

(52) U.S. Cl. 331/75; 331/77; 331/116 FE; 331/158

(57) ABSTRACT

An amplification circuit includes an inverter whose input node is connected to an output node of an oscillation circuit and a resistance element connected in parallel with the inverter. A filter circuit is connected to an input node of the amplification circuit, and both a level-shift circuit and a Schmitt circuit are connected to a stage subsequent to the filter circuit. The filter circuit, level-shift circuit and Schmitt circuit eliminate noise from an oscillation signal. The Schmitt circuit wave-shapes the oscillation signal and outputs the wave-shaped signal as a clock.

### CROSS-REFERENCE TO RELATED APPLICATIONS

This application is based upon and claims the benefit of priority from the prior Japanese Patent Application No. 11-370872, filed Dec. 27, 1999, the entire contents of which are incorporated herein by reference.

### BACKGROUND OF THE INVENTION

The present invention relates to an oscillation/amplification circuit and, more particularly, to measures against noise of an oscillation/amplification circuit for generating a clock for driving a microprocessor.

Recently, digital circuit technology has advanced remarkably, and a large number of devices are equipped with a microprocessor (CPU: Central Processing Unit). Peripheral circuits for operating the CPU require operating with a high degree of reliability.

The CPU operates in response to a clock. It is an oscillation/amplification circuit that generates the clock. The arrangement of a prior art oscillation/amplification circuit will now be described with reference to FIG. 1. FIG. 1 is a schematic circuit diagram of the prior art oscillation/amplification circuit.

As FIG. 1 shows, an oscillation/amplification circuit 10 comprises an oscillation circuit 20, an amplification circuit 30, and a Schmitt circuit 40. The oscillation circuit 20 includes wave-shaping capacitors 21 and 22 and a quartz oscillator 23. One of electrodes of each of the capacitors 21 and 22 is grounded, and the other electrodes of the capacitors 21 and 22 are connected to their respective ends of the quartz oscillator 23.

The amplification circuit 30 includes a CMOS inverter 31 whose input node is connected to one end of the quartz oscillator 23, a feedback resistor 32 interposed between the input and output nodes of the CMOS inverter 31, and a damping resistor 33 provided between the output node of the CMOS inverter 31 and the other end of the quartz oscillator 23. The CMOS inverter 31 includes an nMOS transistor 34 whose gate is connected to the input node of the CMOS inverter 31 and whose source is connected to a ground potential node (GND) and a pMOS transistor 35 whose gate is connected to the input node of the CMOS inverter 31, whose source is connected to a power supply potential node (Vcc), and whose drain is connected to the drain of the nMOS transistor 34. A connection node between the drains of the nMOS and pMOS transistors 34 and 35 corresponds to the output node of the CMOS inverter 31.

The input node of the Schmitt circuit 40 is connected to the output node of the CMOS inverter 31. The output of the Schmitt circuit 40 serves as an output (clock) of the oscillation/amplification circuit 10.

Generally, the amplification circuit 30 and the Schmitt circuit 40 are integrated as a one-chip semiconductor integrated circuit 50. The oscillation circuit 20 is connected to input terminals IN1 and IN2 of the circuit 50 to constitute the oscillation/amplification circuit 10.

The frequency of an oscillation signal generated from the oscillation circuit 20 depends upon the characteristics of the quartz oscillator 23 and the capacities of the capacitors 21 and 22. First, the amplification circuit 30 amplifies the oscillation signal. Then, the Schmitt circuit 40 reduces noise from the amplified oscillation signal and shapes the waveform thereof. The signal is thus output as a clock from an output terminal OUT.

In the prior art oscillation/amplification circuit described above, the Schmitt circuit decreases an influence of noise upon the clock; however, only the Schmitt circuit may be insufficient to reduce noise. This problem will be explained with reference to FIG. 2. FIG. 2 is a schematic diagram of a circuit board mounted with the foregoing oscillation/amplification circuit 10.

As FIG. 2 illustrates, the oscillation circuit (Osc.) 20, semiconductor integrated circuits (LSIs) 61 and 62, and AC/DC conversion circuit 63 are arranged on a PCB (printed circuit board) 60. The amplification circuit 30 is integrated on the semiconductor integrated circuit 61, and the oscillation circuit 20 and the semiconductor integrated circuit 61 constitute the oscillation/amplification circuit. The AC/DC conversion circuit 63 converts an AC power supply voltage applied from an AC power supply 64 into a DC power supply voltage. Further, a power supply line (Vcc) and a ground potential line (GND) common to the respective elements are formed on the PCB 60, and these lines are supplied with the DC power supply voltage generated by the AC/DC conversion circuit 63.

It is the AC power supply 64 and the semiconductor integrated circuit 62 that mainly cause noise in the foregoing oscillation/amplification circuit. Extraneous noise caused by the AC power supply 64 is attenuated to some extent by elements such as a transformer and a capacitor constituting the AC/DC conversion circuit 63 and sent to the power line on the PCB 60. Noise caused by the semiconductor integrated circuit 62 is switching noise, which is also sent to the power line.

The above extraneous noise and switching noise are transmitted to the semiconductor integrated circuits on the PCB 60 through all portions connected to the power line, such as a power supply/GND terminal, a reset terminal, and an I/O port. If the oscillation/amplification circuit 10 shown in FIG. 1 is mounted on the PCB 60, noise is transmitted from the capacitors 21 and 22 of the oscillation circuit 20 as well as the power supply/GND terminal.

Since the above noise transmission is expected on the PCB 60, it is general to provide anti-noise elements such as a capacitor, a resistor, a ferrite bead and a choke coil. The effects of these elements will be described with reference to FIG. 3. FIG. 3 shows power supply potential Vcc and ground potential GND on the PCB 60 which vary with time. As FIG. 3 shows, when noise is mixed into the power line to fluctuate the power supply potential Vcc, the anti-noise elements fluctuate the ground potential GND in the same manner. Observing the power supply potential with reference to the ground potential, a difference between them appears invariable and the power supply potential Vcc appears stable. The operation of fluctuating the power supply potential and the ground potential in the same manner is performed by a capacitor between power supplies in order to maintain a constant difference between the power supply potential and the ground potential. This is a very effective measure against noise.

However, the above measure may not be sufficient to reduce a slight noise such as a high-frequency pulse whose amplitude is small and whose pulse width is about 5 ns to 10 ns such that it does not influence a system of the semiconductor integrated circuits. The high-frequency slight noise is mixed into the oscillation/amplification circuit and adversely influences the clock generated therefrom.

The influence of the slight noise on the clock generated from the oscillation/amplification circuit will be described with reference to FIGS. 4A to 4C. FIGS. 4A to 4C illustrate output waveforms of the oscillation circuit 20, amplification circuit 30 and Schmitt circuit 40, respectively. For simplification, an oscillation signal is defined as a triangular wave. As FIG. 4A shows, the noise transmitted through the capacitors 21 and 22 from the ground potential line is superposed on the oscillation signal generated from the oscillation circuit 20. The amplification circuit 30 amplifies the oscillation signal, together with the noise superposed thereon, as shown in FIG. 4B. The Schmitt circuit 40 shapes the waveform of the oscillation signal. The waveform reflects the noise itself as shown in FIG. 4C.

As described above, the superposition of noise on an oscillation signal in the vicinity of threshold voltage Vth of the CMOS inverter 33 of the amplification circuit 30 causes an unexpected clock to be generated even though the noise is low. If such an unexpected clock is generated, it causes the semiconductor integrated circuits to vary in operation timing and causes the system of the circuits to malfunction.

### BRIEF SUMMARY OF THE INVENTION

It is accordingly an object of the present invention to provide an oscillation/amplification circuit which is unsusceptible to noise and capable of supplying a stable clock.

The above object is obtained by an oscillation/amplification circuit comprising an amplification circuit for amplifying an oscillation signal input to an input node thereof and outputting the amplified oscillation signal from an output node thereof, the amplification circuit having a feedback loop for feeding the oscillation signal of the output node back to the input node, a filter circuit whose input node is connected to the input node of the amplification circuit, for reducing a noise component contained in the oscillation signal amplified by the amplification circuit, and a Schmitt circuit for shaping a waveform of the oscillation signal the noise component of which is reduced by the filter circuit and reducing the noise component further.

The object is also attained by an oscillation/amplification circuit comprising an amplification circuit for amplifying an oscillation signal, a filter circuit for reducing a noise component contained in the oscillation signal amplified by the amplification circuit, a level-shift circuit for shifting a voltage level of the oscillation signal output from the filter circuit and reducing the noise component contained in the oscillation signal, and a Schmitt circuit for shaping a waveform of the oscillation signal the voltage level of which is shifted by the level-shift circuit and reducing the noise component further.

In the circuit arrangement described above, an oscillation signal is supplied to the filter circuit from the input node of the amplification circuit having a feedback loop between the input and output nodes. In other words, the oscillation signal supplied to the filter circuit is a signal whose noise component is not amplified. The filter circuit can eliminate almost all the noise component from the oscillation signal. Since the Schmitt circuit is supplied with the oscillation signal whose noise component is almost eliminated by the filter circuit, it can shape the waveform of the signal almost completely. The influence of the noise component can be reduced and thus a clock can stably be generated, with the result that the cause of a difference in clock timing of a circuit operated by the clock and a malfunction can be eliminated.

Since a voltage level of the oscillation signal output from the filter circuit is shifted by the level-shift circuit, noise can be reduced further and a stable clock can be supplied.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a circuit diagram of a prior art oscillation/amplification circuit;

FIG. 2 is a schematic view of a circuit board on which the prior art oscillation/amplification circuit is mounted;

FIG. 3 is a waveform diagram showing variations in power supply potential and ground potential due to mixture of noise;

FIGS. 4A to 4C are output waveform diagrams of an oscillation circuit, an amplification circuit and a Schmitt circuit in the prior art oscillation/amplification circuit;

FIG. 5 is a schematic block diagram of an oscillation/amplification circuit according to a first embodiment of the present invention;

FIG. 6 is a circuit diagram of the oscillation/amplification circuit according to the first embodiment of the present invention;

FIG. 7 is a circuit diagram of a Schmitt circuit;

FIGS. 8A and 8B are diagrams of input and output waveforms of the Schmitt circuit, respectively;

FIGS. 9A to 9C are diagrams of output waveforms of an oscillation circuit, an amplification circuit and a Schmitt circuit of the oscillation/amplification circuit according to the first embodiment of the present invention;

FIG. 10 is a circuit diagram of an oscillation/amplification circuit according to a modification to that of the first embodiment of the present invention;

FIGS. 11A to 11D are diagrams of output waveforms of an oscillation circuit, an amplification circuit, a filter circuit and a Schmitt circuit of the oscillation/amplification circuit according to the modification to that of the first embodiment of the present invention;

FIG. 12 is a circuit diagram of an oscillation/amplification circuit according to a second embodiment of the present invention;

FIG. 13 is a circuit diagram of a level-shift circuit;

FIGS. 14A and 14B are diagrams of input and output waveforms of the level-shift circuit, respectively;

FIGS. 15A to 15E are diagrams of output waveforms of an oscillation circuit, an amplification circuit, a filter circuit, a level-shift circuit and a Schmitt circuit of the oscillation/amplification circuit according to the second embodiment of the present invention;

FIG. 16 is a circuit diagram of an oscillation/amplification circuit according to a third embodiment of the present invention;

FIGS. 17A to 17D are circuit diagrams of oscillation/amplification circuits according to the first to fourth modifications to those of the first to third embodiments of the present invention;

FIGS. 18A to 18D are diagrams of output waveforms of an oscillation circuit, an amplification circuit, a filter circuit and a Schmitt circuit of the oscillation/amplification circuit according to the fourth modification to those of the first to third embodiments of the present invention; and

FIG. 19 is a schematic diagram of an oscillation/amplification circuit according to a fifth modification to those of the first to third embodiments of the present invention.

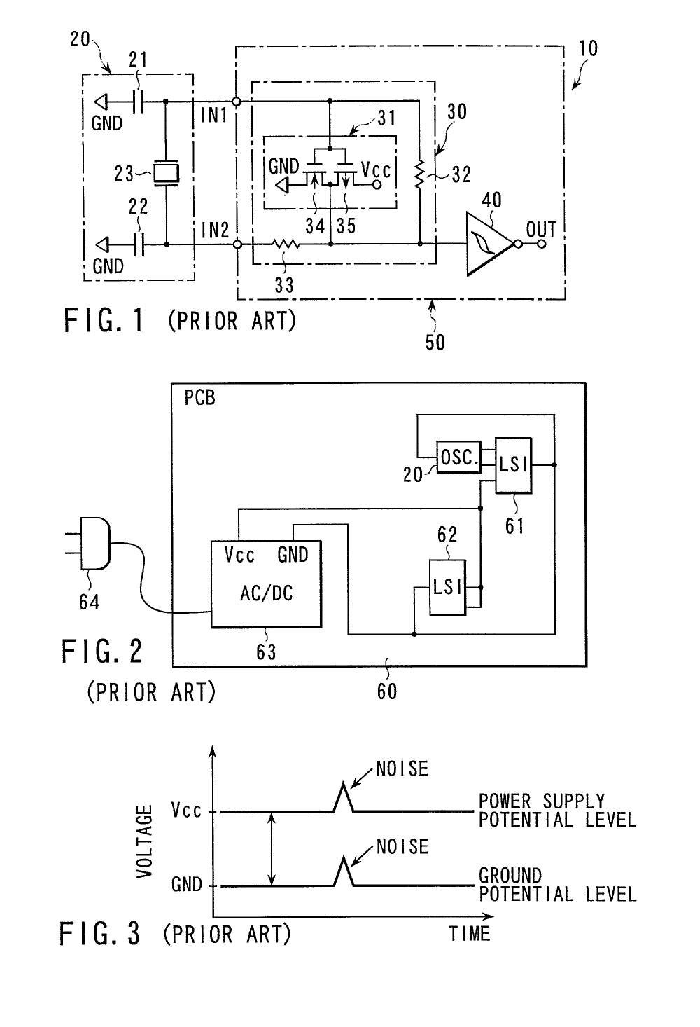

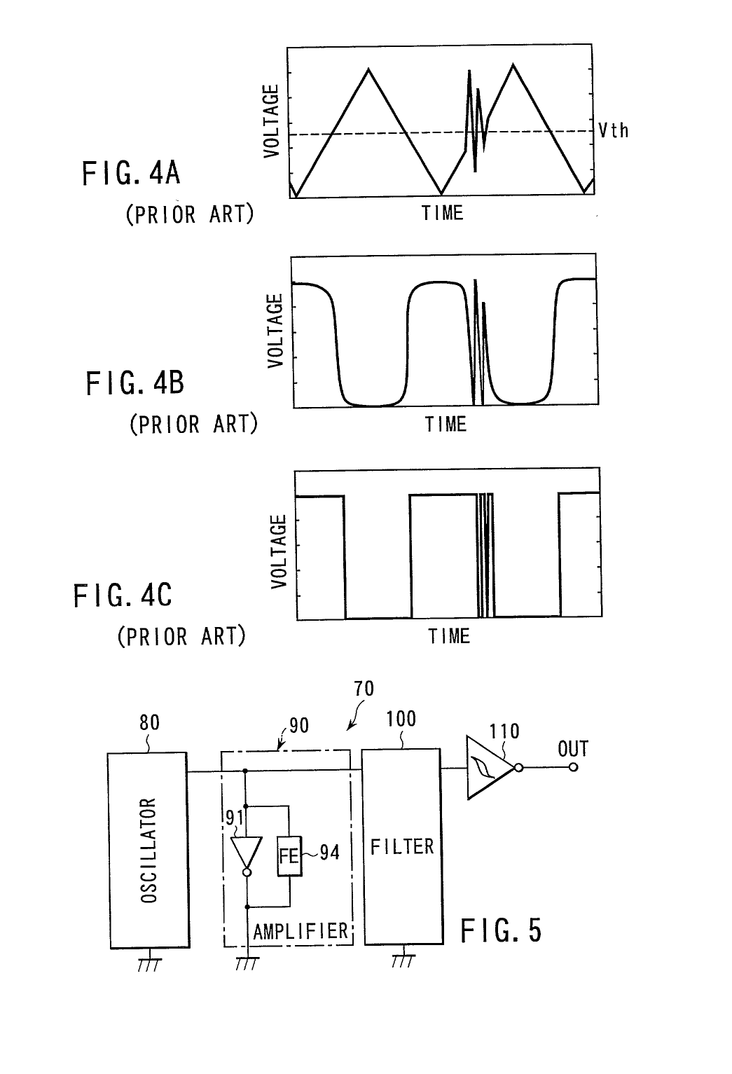

### DETAILED DESCRIPTION OF THE INVENTION

An oscillation/amplification circuit according to a first embodiment of the present invention will now be described with reference to FIG. 5. FIG. 5 is a schematic block diagram of the oscillation/amplification circuit.

As shown in FIG. 5, an oscillation/amplification circuit 70 comprises an oscillation circuit 80, an amplification circuit 90, a filter circuit 100, and a Schmitt circuit 110.

The oscillation circuit 80 generates an oscillation signal. The amplification circuit 90 includes an inverter 91. The output node of the circuit 80 is connected to the input node of the inverter 91. The amplification circuit 90 also includes a load element (FE: feedback element) 94 arranged in parallel with the inverter 91. The load element 94 is a bias element for providing the inverter 91 or the oscillation circuit 80 with a potential.

The input node of the filter circuit 100 is connected to that of the amplification circuit 90. The Schmitt circuit 110 shapes the waveform of an output signal of the filter circuit 100. The signal is thus output as a clock from the output terminal OUT of the Schmitt circuit 110.

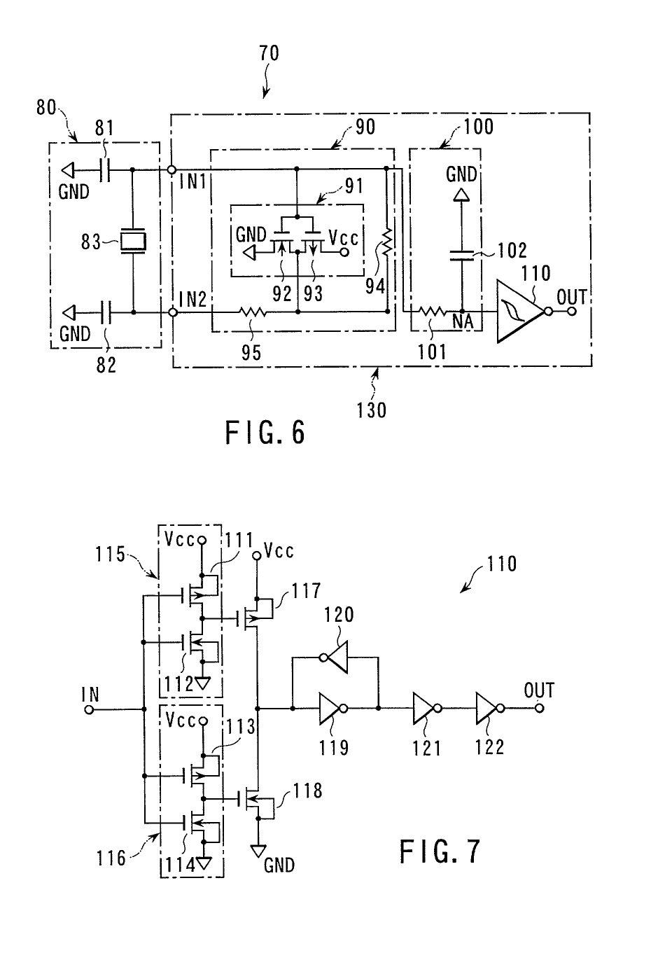

The circuit arrangement embodying the respective elements of the oscillation/amplification circuit 70 will be described with reference to FIG. 6. FIG. 6 is a circuit diagram of the oscillation/amplification circuit.

The oscillation circuit 80 includes wave-shaping capacitors 81 and 82 and a quartz oscillator 83. One electrode of each of the capacitors 81 and 82 is grounded, and both ends of the quartz oscillator 83 are connected to the other electrodes of the capacitors 81 and 82.

The amplification circuit 90 includes a CMOS inverter 91 whose input node is connected to a connection node between the capacitor 81 and quartz oscillator 83 of the oscillation circuit 80. The CMOS inverter 91 includes an nMOS transistor 92 whose gate is connected to the connection node and whose source is connected to a ground potential node and a pMOS transistor 93 whose gate is connected to the connection node, whose drain is connected to that of the nMOS transistor 92, and whose source is connected to a power supply potential node. A connection node of the nMOS and pMOS transistors 92 and 93 serves as an output node of the CMOS inverter 91. A bias load element 94 is provided between input and output nodes of the CMOS inverter 91 and, in this circuit, it serves as a resistance element (feedback resistor) 94. Further, a damping resistor 95 is interposed between a connection node of the capacitor 82 and quartz oscillator 83 of the oscillation circuit 80 and the output node of the CMOS inverter 91.

The filter circuit 100 is constituted of a first-stage RC circuit including a resistance element 101 and a capacitor 102. The input node of the circuit 100 is connected to that of the CMOS inverter 91 of the amplification circuit 90. The input node of the Schmitt circuit 110 is connected to the output node of the filter circuit 100.

Usually the amplification circuit 90, filter circuit 100, and Schmitt circuit 110 are integrated as a one-chip semiconductor integrated circuit 130. The oscillation circuit 80 is connected to terminals IN1 and IN2 of the circuit 130 to constitute the oscillation/amplification circuit 70.

An example of the arrangement of the Schmitt circuit 110 will now be described with reference to FIG. 7. FIG. 7 is a circuit diagram of the Schmitt circuit 110.

As FIG. 7 illustrates, the Schmitt circuit 110 includes CMOS inverters 115 and 116. The CMOS inverter 115 has a pMOS transistor 111 and an nMOS transistor 112, and the CMOS inverter 116 has a pMOS transistor 113 and an nMOS transistor 114. The input nodes of the CMOS inverters 115 and 116 or the gates of the MOS transistors 111 to 114 serve as the input node of the Schmitt circuit 110, and this input node is connected to the output node of the filter circuit 100. The sources of the pMOS transistors 111 and 113 are connected to their respective power supply potential nodes, while those of the nMOS transistors 112 and 114 are connected to their respective ground potential nodes. The drains of the pMOS and nMOS transistors 111 and 112 are connected to each other and a connection node between them serves as the output node of the CMOS inverter 115. The drains of the pMOS and nMOS transistors 113 and 114 are connected to each other and a connection node between them serves as the output node of the CMOS inverter 116.

The output node of the CMOS inverter 115 is connected to the gate of a pMOS transistor 117 whose source is connected to a power supply potential. The output node of the CMOS inverter 116 is connected to the gate of an nMOS transistor 118 whose source is connected to a ground potential node and whose drain is connected to that of the pMOS transistor 117.

The connection node between the drains of the pMOS and nMOS transistors 117 and 118 is connected to the input node of an inverter 119. The inverter 119 constitutes a data latch, together with an inverter 120 whose input node is connected to the output node of the inverter 119 and whose output node is connected the input node of the inverter 119. Inverters 121 and 122 are also connected in series to the output node of the inverter 119. The output node of the inverter 122 serves as an output node of the Schmitt circuit 110.

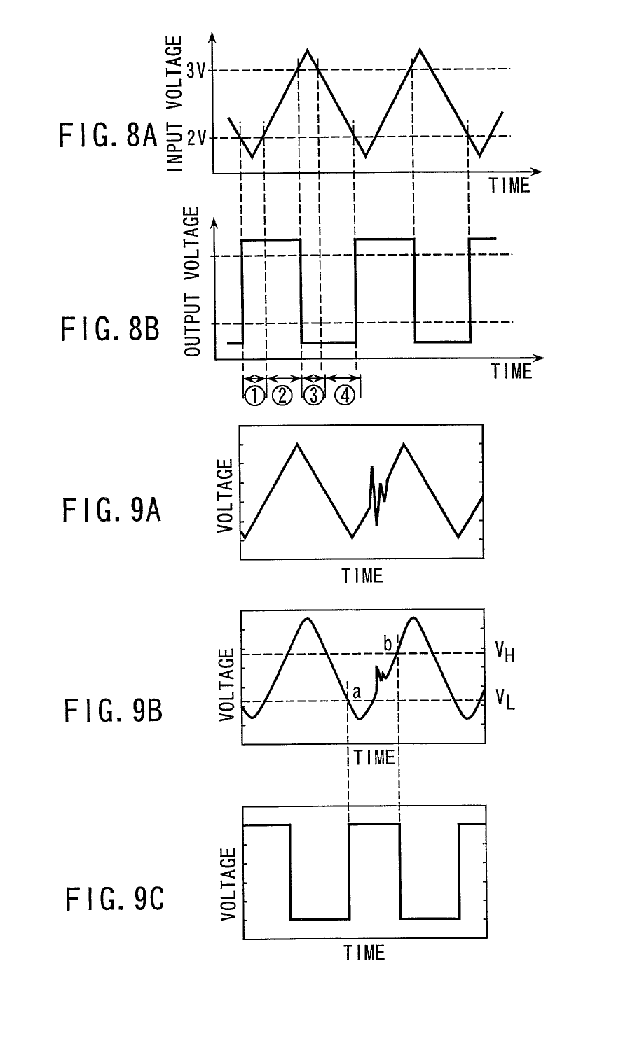

An operation of the Schmitt circuit having the above arrangement will now be described briefly with reference to FIGS. 8A and 8B. FIG. 8A is a waveform diagram of the voltage input to the Schmitt circuit, and FIG. 8B is a waveform diagram of the voltage output therefrom. The Schmitt circuit has the striking feature that its threshold voltage Vth varies from a high-level (“H”) output signal to a low-level (“L”) output signal and has a hysteresis characteristic as an input/output characteristic. Assume that the threshold voltages of the CMOS inverters 115 and 116 of the Schmitt circuit 110 are 3V and 2V, respectively.

First, a triangular wave is input to the Schmitt circuit as illustrated in FIG. 8A. In a time zone \mathring{1} (the input voltage is 2V or lower) shown in FIG. 8B, the MOS transistors 111 and 113 turn on and the MOS transistors 112 and 114 turn off; accordingly, the nMOS transistor 118 turn on. A low-level signal is therefore output from the connection node of the MOS transistors 117 and 118. The low-level signal is wave-shaped and inverted by the inverters 119, 121 and 122. The Schmitt circuit outputs a high-level signal.

In a time zone \mathring{2}(the input voltage rises from 2V to 3V) shown in FIG. 8B, the input voltage exceeds the threshold voltage of the CMOS inverter 116, and the MOS transistors 111 and 114 turn on, while the MOS transistors 112 and 113 turn off. Both the two MOS transistors 117 and 118 connected to the output nodes of the CMOS inverters 115 and 116 turn off. In this case, the output signal in the time zone \mathring{1}latched by the inverter 120 is output through the inverters 119, 121 and 122; thus, the output of the Schmitt circuit 110 is maintained at a high level.

In a time zone \mathring{3}(the input voltage is 3V or higher) shown in FIG. 8B, the input voltage exceeds the threshold voltage of the CMOS inverter 115. The nMOS transistors 112 and 114 turn on, while the pMOS transistors 111 and 113 turn off. The pMOS transistor 117 turn on. A high-level signal is therefore output from the connection node of the MOS transistors 117 and 118. The high-level signal is wave-shaped and inverted by the inverters 119, 121 and 122, and a low-level signal is output from the Schmitt circuit 110.

In a time zone \mathring{4}(the input voltage drops from 3V to 2V) shown in FIG. 8B, the input voltage becomes lower than the threshold voltage of the CMOS inverter 115. The MOS transistors 111 and 114 turn on, while the MOS transistors 112 and 113 turn off. As in the time zone \mathring{2}, both the two MOS transistors 117 and 118 connected to the connection node of the CMOS inverters 115 and 116 turn off. However, in this case, too, the output signal of the time zone \mathring{3}latched by the inverter 120 is output through the inverters 119, 121 and 122. The output of the Schmitt circuit 110 is thus maintained at a low level. When the input voltage further drops to 2V or lower, the above operation is repeated from the time zone \mathring{1}.

An operation of the oscillation/amplification circuit shown in FIG. 6, which comprises the Schmitt circuit having the above arrangement, will now be described with reference to FIGS. 9A to 9C. FIGS. 9A to 9C are waveform diagrams of the oscillation circuit 80 (terminal IN1 in FIG. 6), the filter circuit 100 (node NA in FIG. 6), and the Schmitt circuit 110 (terminal OUT in FIG. 6), respectively. These waveform diagrams are obtained by computer simulation, and the circuit arrangement used for the simulation corresponds to that shown in FIG. 6 from which the oscillation circuit 80 is excluded. The waveform shown in FIG. 9A is regarded as that of an oscillation signal generated from the oscillation circuit 80. Assuming that this waveform is input to the amplification circuit 90, the simulation was performed. In this simulation, the oscillation is in a stable state as shown in FIG. 6, and the noise determined by actual measurement is superposed on the oscillation signal. The resistance of the resistor 101 of the filter circuit 100 is 2000 Ω and the capacity of the capacitor 102 is 3 pF.

First, the oscillation circuit 80 generates an oscillation signal as shown in FIG. 9A. The frequency of the oscillation signal depends upon the characteristics of the quartz oscillator 83 and the capacities of capacitors 81 and 82. Since one end of each of the capacitors 81 and 82 is connected to a ground potential node as in the prior art, it is impossible to prevent a slight noise from being mixed from the node. Assume that the noise is superposed on a voltage which is close to the threshold voltage Vth of the CMOS inverter 91 of the amplification circuit 90.

Then, the oscillation signal on which the noise is superposed is supplied to the amplification circuit 90. At the same time, it is also supplied to the input node of the filter circuit 100 directly. In other words, an oscillation signal, which is amplified containing noise by the CMOS inverter 91, is not input to the filter circuit 100. The feedback resistor 94 applies a bias to the inverter 91. This bias is naturally applied to the oscillation circuit 80, too. The oscillation signal itself is amplified accordingly. However, the noise mixed from the ground potential node is not amplified but supplied to the filter circuit 100 directly from the terminal IN1. Thus, the oscillation signal the noise of which is not amplified is input to the filter circuit 100.

The filter circuit 100 eliminates noise from the oscillation signal shown in FIG. 9A and outputs an oscillation signal as shown in FIG. 9B. Since the pulse width of the high-frequency noise in question is only 5 ns to 10 ns at the most, the noise can greatly be reduced if the rising and falling edges of the signal are delayed by the filter circuit (RC circuit) 100.

The oscillation signal whose noise is reduced by the filter circuit 100 is supplied to the Schmitt circuit 110 and then wave-shaped by the Schmitt circuit 110. The Schmitt circuit 110 thus generates a clock as shown in FIG. 9C. The Schmitt circuit 100 has hysteresis as input/output characteristics as described above. As FIGS. 9B and 9C show, a point a at which an output voltage of the filter circuit 100 reaches a rising threshold voltage V_{L} of the Schmitt circuit 110, corresponds to the rising trigger of the Schmitt circuit 110. A point b at which the output voltage of the filter circuit 100 rises to a falling threshold voltage V_{H} of the Schmitt circuit 110, corresponds to the falling trigger of the circuit 110, and the output thereof is inverted. Since the noise superposed on the time zone between the rising and falling edges is smoothened by the filter circuit 100, it does not reach the falling threshold voltage V_{H}. For this reason, the noise does not influence the output of the Schmitt circuit 110, and the waveform of the output is shaped almost completely.

According to the oscillation/amplification circuit so arranged, not the output node but the input node of the inverter 91 is connected to the input node of the filter circuit 100. Since the noise superposed on the oscillation signal input to the filter circuit is not amplified but remains low, the filter circuit 100 can eliminate almost all the noise. Since the Schmitt circuit 110 receives the oscillation signal the noise of which is almost eliminated, it can wave-shape its output perfectly. The Schmitt circuit can thus supply a normal clock to a circuit constantly without being influenced by the noise, thereby eliminating the cause of a difference in clock timing of the circuit operated by the normal clock and a malfunction.

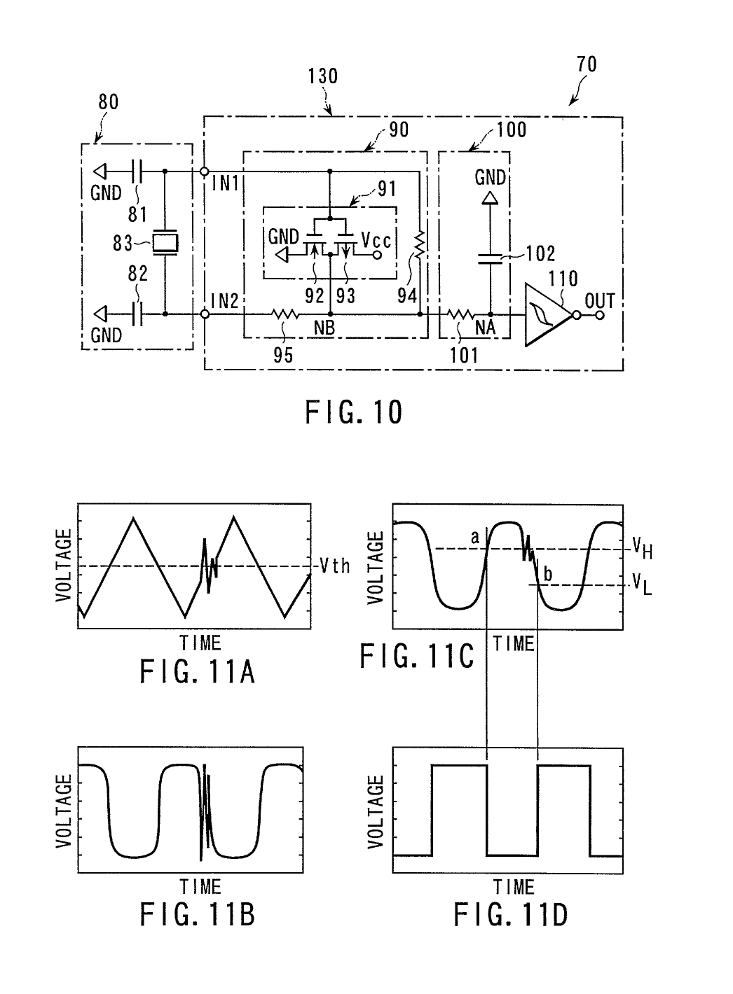

FIG. 10 is a circuit diagram of an oscillation/amplification circuit according to a modification to that of the first embodiment of the present invention. In the first embodiment, the input node of the inverter 91 is connected to that of the filter circuit 100, whereas in the modification the output node of the inverter 91 is connected to the input node of the filter circuit 100.

An operation of the oscillation/amplification circuit according to the modification will now be described with reference to FIGS. 11A to 11D. FIGS. 11A to 11D are waveform diagrams of the oscillation circuit 80 (terminal IN1 in FIG. 10), the amplification circuit 90 (node NB in FIG. 10), the filter circuit 100 (node NA in FIG. 10), and the Schmitt circuit 110 (terminal OUT in FIG. 10), respectively. The resistance of the resistor 101 of the filter circuit 100 is 2000 Ω and the capacity of the capacitor 102 is 3 pF.

First, the oscillation signal shown in FIG. 11A on which noise is superposed, is input to the amplification circuit 90. In the amplification circuit 90, the CMOS inverter 91 turns on and off repeatedly due to an influence of noise superposed on a voltage which is close to a threshold voltage Vth. The waveform of an output of the amplification circuit 90 is therefore distorted as shown in FIG. 11B.

The oscillation signal, which is amplified together with the noise superposed thereon, is input to the filter circuit 100. The filter circuit 100 eliminates the noise from the amplified oscillation signal shown in FIG. 11B and outputs an oscillation signal as shown in FIG. 11C.

The Schmitt circuit 110 shapes the waveform of the oscillation signal shown in FIG. 11C, the noise of which is reduced by the filter circuit 100, and generates a clock as shown in FIG. 11D. In the output signal of the filter circuit 110 shown in FIG. 11C, a point a at which the output voltage reaches a falling threshold voltage V_{H} of the Schmitt circuit 110, corresponds to the falling trigger of the output signal of the Schmitt circuit. A point b at which the output voltage of the filter circuit 100 drops to a rising voltage V_{L} of the Schmitt circuit 110, corresponds to the rising trigger of the output signal of the Schmitt circuit 110, and the output thereof is inverted. The noise between the falling and rising edges is smoothened by the filter circuit 100 and does not reach the falling voltage V_{L}. The noise does not influence the output of the Schmitt circuit 110, and the waveform of the output is shaped almost completely.

In the oscillation/amplification circuit described above, the oscillation signal generated from the oscillation circuit 80 is amplified first by the amplification circuit 90 as in the prior art. If noise is superposed on the oscillation signal, it is also amplified. However, the amplified signal is input to the Schmitt circuit 110 not directly but through the filter circuit 100 by which the noise is reduced from the signal. If the filter circuit 100 and the Schmitt circuit 110 can eliminate the noise from the oscillation signal amplified by the amplification circuit 90, the circuit can be arranged as illustrated in FIG. 10.

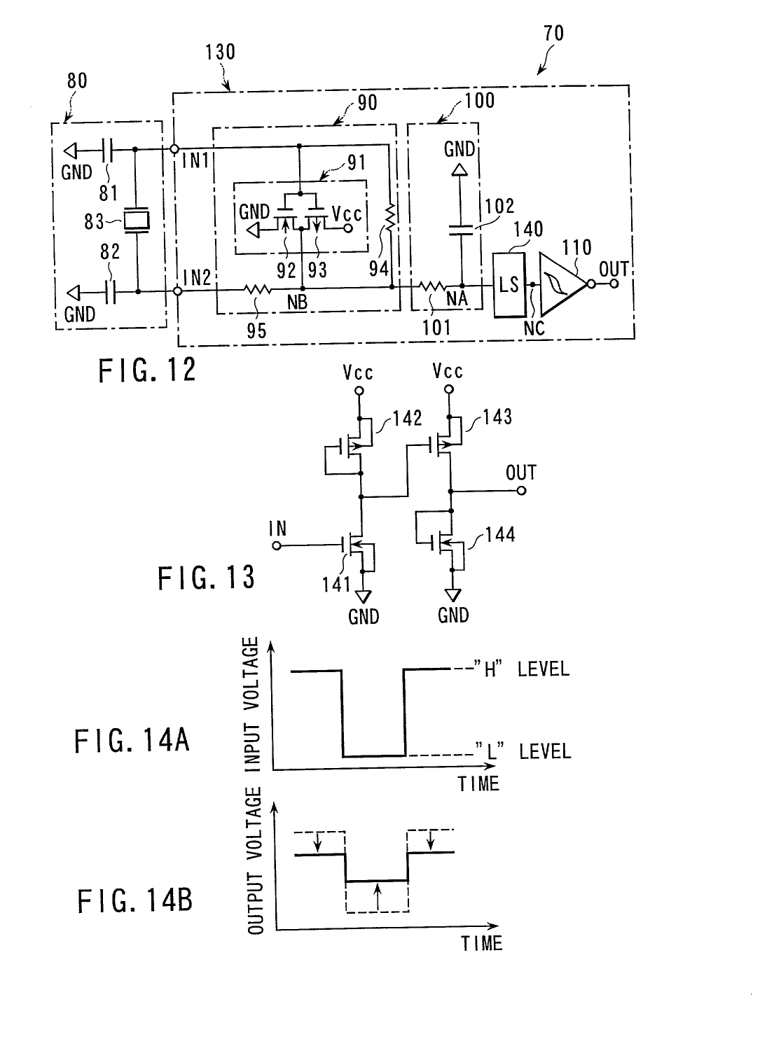

An oscillation/amplification circuit according to a second embodiment of the present invention will now be described with reference to FIG. 12. FIG. 12 is a circuit diagram of the oscillation/amplification circuit.

As FIG. 12 shows, a level-shift circuit (LS) 140 is provided between the output node of the filter circuit 100 and the input node of the Schmitt circuit 110 in the above modification to the first embodiment.

FIG. 13 is a circuit diagram showing a specific example of the arrangement of the level-shift circuit 140. The level-shift circuit 140 includes an nMOS transistor 141 whose gate is connected to an input node of the level-shift circuit and whose source is connected to a ground potential node, a pMOS transistor 142 whose source is connected to a power supply potential node and whose gate and drain are connected to the drain of the nMOS transistor 141, a pMOS transistor 143 whose gate is connected to a connection node between the drain of the nMOS transistor 141 and that of the pMOS transistor 142 and whose source is connected to a power supply potential node, and an nMOS transistor 144 whose source is connected to a ground potential node and whose gate and drain are connected to the drain of the pMOS transistor 143. A connection node between the drain of the pMOS transistor 143 and that of the nMOS transistor 144 serves as an output node of the level-shift circuit.

An operation of the level-shift circuit having the above arrangement will now be described with reference to FIGS. 14A and 14B. FIGS. 14A and 14B are waveform diagrams showing the input and output voltages of the level-shift circuit which vary as time passes.

As FIG. 14A shows, when the level-shift circuit 140 receives a high-level signal from the input node thereof, it shifts a voltage level of the signal by the MOS transistors 141 and 142 in the first stage and decreases the potential at the output node thereof down to a value of Vcc−Vth (Vth is a threshold voltage of the pMOS transistor 142). When the level-shift circuit 140 receives a low-level signal, it shifts a voltage level of the signal by the MOS transistors 143 and 144 in the second stage and increases the potential up to a value of GND+Vth′ (Vth′ is a threshold voltage of the nMOS transistor 144).

The range of voltage shifted by the level-shift circuit 140 can freely be set by varying the size of the MOS transistors 141 to 144. If the level-shift circuit varies in arrangement, it can shifts the voltage of only one of high-level and low-level signals.

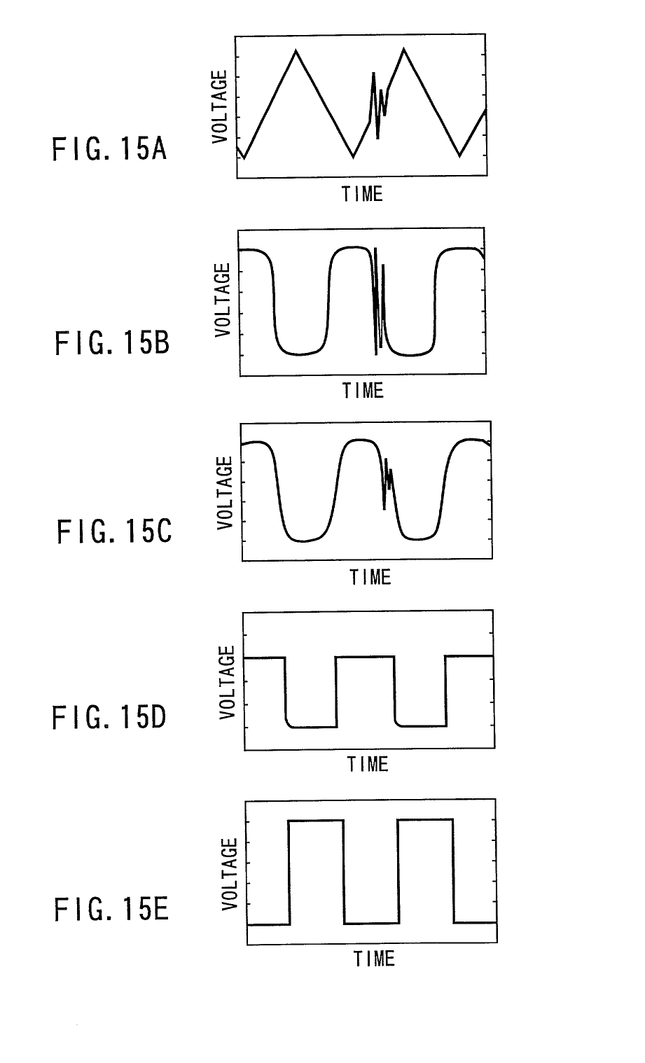

An operation of the oscillation/amplification circuit shown in FIG. 12, which comprises the above level-shift circuit, will now be described with reference to FIGS. 15A to 15E. FIGS. 15A to 15E are waveform diagrams of the oscillation circuit 80 (terminal IN1 in FIG. 12), the amplification circuit 90 (node NB in FIG. 12), the filter circuit 100 (node NA in FIG. 12), the level-shift circuit 140 (node NC in FIG. 12), and the Schmitt circuit 110 (terminal OUT in FIG. 12), respectively. The resistance of the resistor 101 of the filter circuit 100 is 500 Ω and the capacity of the capacitor 102 is 3 pF.

The oscillation/amplification operation performed to the filter circuit 100 is the same as that of the modification to the first embodiment and thus its description is omitted. When the level-shift circuit 140 receives an oscillation signal as shown in FIG. 15C from the output node of the filter circuit 100, it shifts a voltage level of the oscillation signal. The shift in voltage level allows noise, which is superposed on a voltage close to the threshold voltage Vth of the CMOS inverter 91, to be eliminated almost completely, and the level-shift circuit 140 outputs a signal having the waveform shown in FIG. 15D.

The circuit 140 supplies the signal to the input node of the Schmitt circuit 110. The circuit 110 shapes the waveform of the signal and generates a clock as shown in FIG. 15E.

The advantage of the level-shift circuit 140 will be described hereinafter. The level-shift circuit is provided to eliminate noise as described above. In the stage precedent to the level-shift circuit, the filter circuit 100 is provided for the same purpose. The filter circuit 100 is constituted of an RC (resistance-capacitance) circuit, and a degree of delay in noise can be set by the resistance and capacity (time constant: RC) of the RC circuit. If the time constant increases, the degree can be heightened and, in other words, the waveform can be smoothened further and thus the filter circuit can be improved in performance. However, the increase in time constant will greatly delay the original oscillation signal. If, therefore, the oscillation signal increases in frequency, it is likely to be eliminated. Conversely, if the time constant decreases, the degree of delay can be lowered and thus the oscillation signal is hardly likely to be eliminated; however, in this case, a noise elimination effect is reduced. In the circuit arrangement according to the modification to the first embodiment, the amplification circuit 90 amplifies an oscillation signal together with noise contained therein. Since the amplification circuit 90 amplifies noise, there is a case where only the filter circuit 100 and Schmitt circuit 110 cannot eliminate the noise completely.

If the level-shift circuit 140 is provided in the stage subsequent to the filter circuit 100, it can heighten and lower a voltage level to eliminate noise more greatly. Even though the filter circuit 100 does not eliminate noise sufficiently, the level-shift circuit 140 can compensate for the insufficiency. It is thus possible to prevent noise from influencing the waveform of an output of the Schmitt circuit 110. Since the influence of noise can be eliminated by the level-shift circuit 140 as well as the filter circuit 100 and the Schmitt circuit 110, the Schmitt circuit can output a normal clock constantly, thereby eliminating the cause of a difference in the clock timing of a circuit and a malfunction.

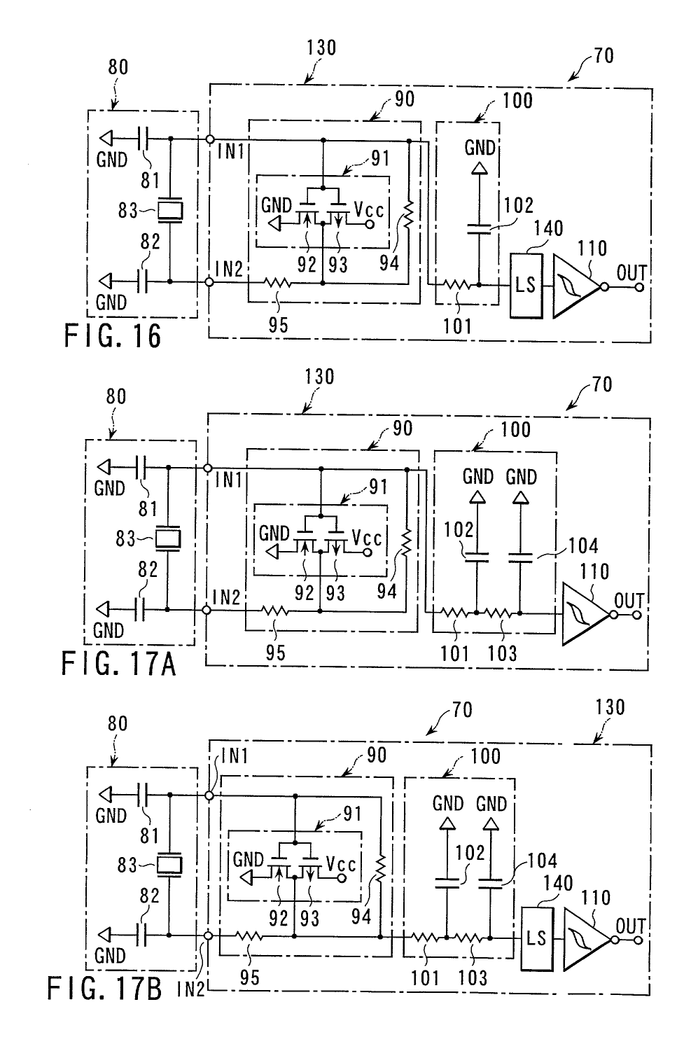

An oscillation/amplification circuit according to a third embodiment of the present invention will now be described with reference to FIG. 16. FIG. 16 is a circuit diagram of the oscillation/amplification circuit.

As FIG. 16 shows, a level-shift circuit 140 is provided between the output node of the filter circuit 100 and the input node of the Schmitt circuit 110 in the first embodiment described above. Since the operation of the level-shift circuit 140 is almost the same as that of the circuit 140 in the second embodiment, its description is omitted.

In the oscillation/amplification circuit according to the third embodiment, the input node of the amplification circuit 90 is connected to that of the filter circuit 100 to supply an oscillation signal to the filter circuit 100 without amplifying noise. The filter circuit 100, level-shift circuit 140 and Schmitt circuit 110 eliminate the noise and shape the waveform of the signal. The noise elimination effect of the third embodiment is therefore greater than those of the first and second embodiments. The oscillation/amplification circuit of the third embodiment can be operated with a high degree of reliability.

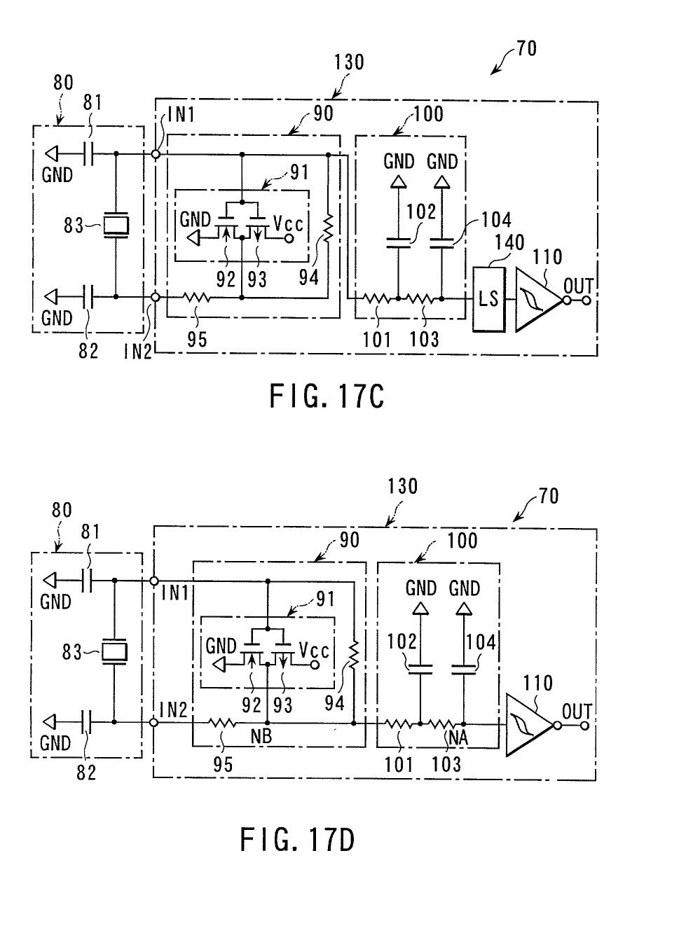

FIGS. 17A to 17D are circuit diagrams of oscillation/amplification circuits according to the first to fourth modifications to those of the first to third embodiments of the present invention.

More specifically, FIGS. 17A to 17D correspond to the oscillation/amplification circuit of the first embodiment shown in FIG. 6, that of the second embodiment shown in FIG. 12, that of the third embodiment shown in FIG. 16, and that of the modification to the first embodiment shown in FIG. 10, respectively. In the circuit arrangement shown in each of FIGS. 17A to 17D, a resistance element 103 and a capacitor 104 are added to the filter circuit 100 to increase the number of RC circuits to two. The circuit arrangement allows the noise elimination effect of the filter circuit to be enhanced further.

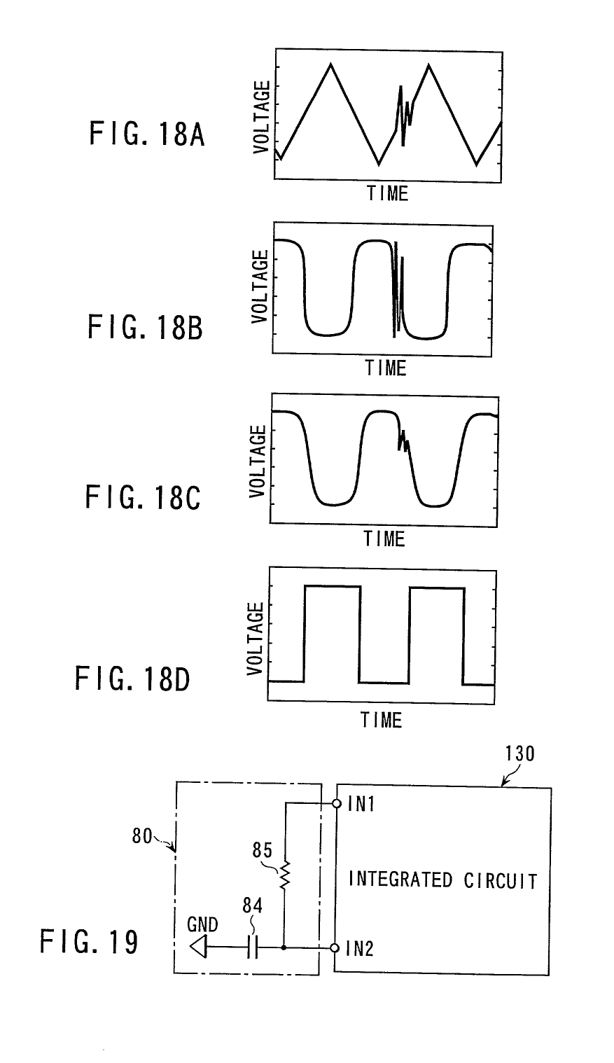

As a representative one of the circuits shown in FIGS. 17A to 17D, an operation of the circuit shown in FIG. 17D will now be described briefly with reference to FIGS. 18A to 18D. FIGS. 18A to 18D are waveform diagrams of the oscillation circuit 80 (terminal IN1 in FIG. 17D), the amplification circuit 90 (node NB in FIG. 17D), the filter circuit 100 (node NA in FIG. 17D), and the Schmitt circuit 110 (terminal OUT in FIG. 17D), respectively. The resistance of the resistance element 101 of the filter RC circuit 100 is 1900 Ω and the capacity of the capacitor 102 is 0.5 pF, while the resistance of the resistance element 103 of the second RC circuit 102 is 100 Ω and the capacity of the capacitor 104 is 2.5 pF.

Assume that noise is superposed on an oscillation signal generated from the oscillation circuit 80 as shown in FIG. 18A. The oscillation signal is amplified by the amplification circuit 90, together with the noise (see FIG. 18B). The noise amplified with the oscillation signal is eliminated by the filter circuit 100 (see FIG. 18C) and then wave-shaped by the Schmitt circuit 110. The circuit 110 thus generates a clock as shown in FIG. 18D.

It is seen that the noise elimination effect of the filter circuit 100 is greater than that of the filter circuit 100 (FIG. 11C) constituted of one RC circuit.

The increase in the number of RC circuits constituting the filter circuit 100 improves the operation reliability of the oscillation/amplification circuit. It is needless to say that the filter circuit can be constituted of three or more RC circuits.

FIG. 19 is a schematic diagram of an oscillation/amplification circuit according to a fifth modification to the first to third embodiments of the present invention. The oscillation circuit 80 does not necessarily require a quartz oscillator. As shown in FIG. 19, it can be replaced with an RC oscillation circuit including a resistance element 85 and a capacitor 84.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An oscillation/amplification circuit comprising:
an amplification circuit for amplifying an oscillation signal input to an input node thereof and outputting the amplified oscillation signal from an output node thereof, the amplification circuit having a feedback loop for feeding the oscillation signal of the output node back to the input node;
a filter circuit whose input node is connected to the input node of the amplification circuit, for reducing a noise component contained in the oscillation signal amplified by the amplification circuit; and
a Schmitt circuit for shaping a waveform of the oscillation signal the noise component of which is reduced by the filter circuit and reducing the noise component further.

2. The oscillation/amplification circuit according to claim 1, wherein the amplification circuit comprises:
an inverter having an input node to which the oscillation signal is input; and
a load element provided between the input node of the inverter and an output node thereof, for applying a bias voltage to the inverter.

3. The oscillation/amplification circuit according to claim 1, further comprising a level-shift circuit provided between an output node of the filter circuit and an input node of the Schmitt circuit, for shifting a voltage level of the oscillation signal output from the filter circuit and reducing the noise component contained in the oscillation signal.

4. The oscillation/amplification circuit according to claim 1, wherein the filter circuit is an RC circuit including a resistance element and a capacitor.

5. The oscillation/amplification circuit according to claim 2, wherein the filter circuit is an RC circuit including a resistance element and a capacitor, and the input node of the filter circuit is connected to the input node of the inverter.

6. The oscillation/amplification circuit according to claim 1, further comprising an oscillation circuit for generating the oscillation signal, the oscillation circuit comprising a quartz oscillator.

7. The oscillation/amplification circuit according to claim 1, further comprising an oscillation circuit for generating the oscillation signal, the oscillation circuit comprising an RC circuit including a resistance element and a capacitor.

8. An oscillation/amplification circuit comprising:
an amplification circuit for amplifying an oscillation signal;
a filter circuit for reducing a noise component contained in the oscillation signal amplified by the amplification circuit;
a level-shift circuit for shifting a voltage level of the oscillation signal output from the filter circuit and reducing the noise component contained in the oscillation signal; and
a Schmitt circuit for shaping a waveform of the oscillation signal the voltage level of which is shifted by the level-shift circuit and reducing the noise component further.

9. The oscillation/amplification circuit according to claim 8, wherein the amplification circuit comprises:
an inverter having an input node to which the oscillation signal is input; and
a load element provided between the input node of the inverter and an output node thereof, for applying a bias voltage to the inverter.

10. The oscillation/amplification circuit according to claim 8, wherein the filter circuit is an RC circuit including a resistance element and a capacitor.

11. The oscillation/amplification circuit according to claim 8, further comprising an oscillation circuit for generating the oscillation signal, the oscillation circuit comprising a quartz oscillator.

12. The oscillation/amplification circuit according to claim 8, further comprising an oscillation circuit for generating the oscillation signal, the oscillation circuit comprising an RC circuit including a resistance element and a capacitor.
